(19) United States
(12) Patent Application Publication
(10) Pub. No.: US 2004/0072388 A1
(43) Pub. Date: Apr. 15, 2004

(54) Method of manufacturing semiconductor chip

(76) Inventor: Kazuma Sekiya, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/468,775

(22) PCT Filed: Dec. 6, 2002
(86) PCT No.: PCT/JP02/12830

(30) Foreign Application Priority Data
Dec. 28, 2001 (JP) 2001-400865

(51) Int. Cl. H01L 21/44

(52) U.S. Cl. 438/113

(57) ABSTRACT

A method of manufacturing a semiconductor chip having no cut deformed layer and chipping and having a sufficiently high transverse strength, comprising the steps of, when dividing a semiconductor wafer W formed so that a plurality of circuits are divided by streets on a surface into semiconductor chips for each circuit, forming cut grooves 19a not leading from the rear surfaces to the front surfaces of the streets so that uncut parts 20 are formed on the front surface side of the semiconductor wafer W and applying etching thereto from the rear surface side to edge the rear surface, side faces of the cut grooves, and uncut parts 20, whereby the wafer can be divided into the semiconductor chips.

### TECHNICAL FIELD

The present invention relates to a method of dicing a semiconductor wafer into separate chips.

### BACKGROUND ART

Referring to FIG. 11, a semiconductor wafer W has a plurality of ICs or LSIs defined by crossing streets S on its front side. The semiconductor wafer is ground on the rear side until a desired thickness is reached, and then the semiconductor wafer is diced crosswise into separate chips C.

Alternatively a semiconductor wafer is grooved crosswise on the front side, and the grooves 50 thus made are as deep as the thickness of the final semiconductor wafer, as seen from FIG. 12. A protective tape T sticks to the front side of the grooved semiconductor wafer W. Referring to FIG. 13, the semiconductor wafer having its lattice pattern on the front side is ground on the exposed rear side until the grooves 50 appear to separate the semiconductor wafer into semiconductor chips C (commonly called “pre-dicing method”).

In either dicing method, however, a distortion layer will result on the rear side of the semiconductor wafer, which is subjected to grinding. Likewise, the distortion layer will result on either side of each street S after cutting the semiconductor wafer. Such grinding and cutting distortion layers cause lowering of the anti-breakage strength of the semiconductor chip.

In the hope of increasing the anti-breakage strength of the semiconductor chip, the post-cut semiconductor wafer is chemical-etched on the rear side to remove the cutting and grinding distortion layers, or the semiconductor chip C is chemical-etched on every side other than the front to remove the cutting and grinding distortion layers. Cutting or grinding distortions can be removed by chemical etching, but minute fractures (cracks and breakings) cannot be completely removed from all sides of the semiconductor chip, and therefore, the anti-breakage strength of the semiconductor chip cannot be significantly increased so far as the chemical etching method is used.

What is aimed at by the present invention, therefore, is to improve substantially the anti-breakage strength of the semiconductor chip.

### DISCLOSURE OF INVENTION

To attain this object the present invention provides a method for dicing a semiconductor wafer into separate chips, each bearing an electrical circuit pattern, said semiconductor wafer having a plurality of chips defined by crossing streets on its front side, characterized by comprising at least a grooving step of making grooves along the crossing streets, each groove extending from the rear side of the semiconductor wafer, reaching short of the front side, thus leaving the remaining thickness on the front side; and an etching step of effecting an etching treatment on the rear side of the semiconductor wafer and on the opposite inner sides and the remaining uncut thickness of each groove until the semiconductor wafer is diced into the separate chips.

Each groove may be a V-shaped groove; the etching treatment may be effected by means of dry etching; and the dicing method may further comprise, prior to the grooving step, a step of grinding the semiconductor wafer on the rear side until a desired thickness is reached.

As described above, each groove extends from the rear side of the semiconductor wafer, reaching short of the front side, leaving a certain thickness on the front side. Then, a chemical etching is effected on the rear side of the semiconductor wafer to remove the remaining thickness of each groove. Thus, each chip is free of the cutting and grinding distortion layers and of the fractures on all sides.

In case that the semiconductor wafer is preliminarily ground on the rear side, the grinding distortion layer can be eliminated by the etching treatment, as well.

### BRIEF DESCRIPTION OF DRAWINGS

FIG. 1 is a perspective view of a semiconductor wafer to which the present invention is applied.

FIG. 2 is a perspective view of the semiconductor wafer having a protection member affixed to its front side.

FIG. 3 is a perspective view of a grinding machine to be used in the rear side-grinding step.

FIG. 4 is a perspective view of a dicing machine to be used in the dicing step.

FIG. 5 is an enlarged perspective view of the cutting and alignment means of the dicing machine.

FIG. 6 is a perspective view of a semiconductor wafer having grooves made on the rear side.

FIG. 7 is a sectional view of the back-grooved semiconductor wafer, illustrating the first example of groove shape.

FIG. 8 is a sectional view of the back-grooved semiconductor wafer, illustrating the second example of groove shape.

FIG. 9 illustrates one example of an etching system useful in etching semiconductor wafers.

FIG. 10 is a sectional view of a post-etching semiconductor wafer, illustrating the wafer groove.

FIG. 11 is a perspective view of a halfway-diced semiconductor wafer.

FIG. 12 is a sectional view of the halfway-diced semiconductor wafer having crosswise grooves made on its front side.

FIG. 13 is a sectional view of the halfway-diced semiconductor wafer, which is ground on the rear side until it is cut into separate chips.

### BEST MODE FOR CARRYING OUT THE INVENTION

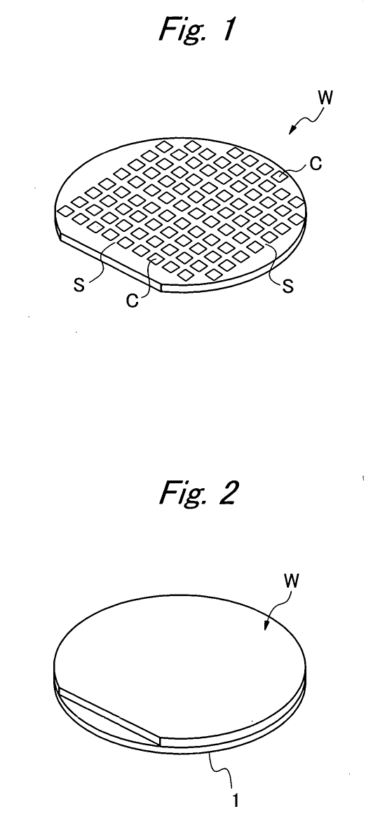

A semiconductor wafer W as shown in FIG. 1 is diced into separate chips each having a good anti-breakage strength according to the present invention.

As seen from FIG. 1, the semiconductor wafer W has a plurality of chips C defined by crossing streets S on its front side. Each square area has ICs, LSIs and other circuits formed thereon.

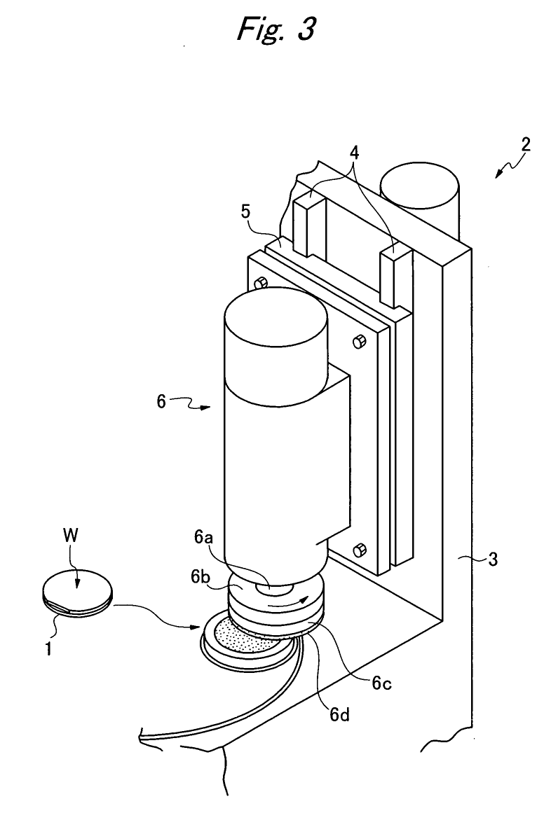

The semiconductor wafer W is placed with the front side down, and a protection member 1 is affixed to the front side of the semiconductor wafer W as shown in FIG. 2. The semiconductor wafer W with the protection member 1 affixed is then transported to a grinding machine 2 as shown in FIG. 3.

The grinding machine 2 shown in FIG. 3 has a pair of parallel rails 4 vertically laid on an inner face of an upright wall 3, and a support 5 rides on the rails 4 so as to allow a grinding unit 6 carried on the support 5 to vertically move, accompanying vertical movement of the support 5 along the rails 4. A turntable 7 has a plurality of chucks 8 rotatably fixed thereto for retaining the semiconductor wafer W.

The grinding unit 6 has a spindle 6a rotatable about its vertical center axis, and the spindle 6a has a mount 6b fixed to its end. The mount 6b has a grinding wheel 6c on its bottom. A grinding stone 6d is fastened to the grinding wheel 6c, so that it can rotate with the spindle 6a.

In the grinding machine 2, the semiconductor wafer W with the protection member 1 affixed is sucked and fixedly held on a selected chuck 8 to bring it directly under the grinding unit 6, while the semiconductor wafer W is held with the rear side up.

Then, the spindle 6a is rotated and the grinding unit 6 is lowered. The spindle 6a and hence the grinding wheel 6d rotate at an increased speed, and the grinding stone 6d is pushed against the semiconductor wafer W on the rear side to grind away its surface until a desired thickness is reached (rear side grinding step).

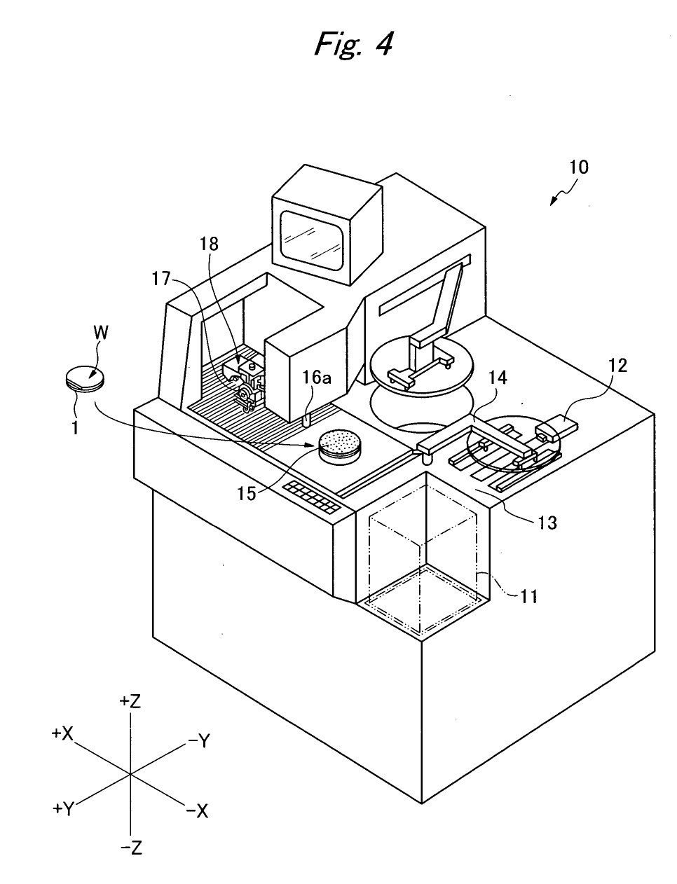

Subsequently, the ground semiconductor wafer W having a desired thickness and with the protection member 1 affixed on the front side is transported to a cutting machine 10 as shown in FIG. 4.

In the cutting machine 10, a plurality of the semiconductor wafers W having a desired thickness and with the protection members 1 affixed on the front side is contained in a cassette 11. They are transferred one by one from the cassette 11 to a tentative storage area 13 by a carrier means 12. Thereafter, a first transporting means 14 sucks the semiconductor wafer with the protection member, and rotates to transport the wafer to a chuck table 15, where the wafer is released on the chuck table 15, and fixedly held with the rear side up on the chuck table 15 by suction.

Then, the chuck table 15 moves in the +x-axial direction to put the wafer W with the protection member 1 right below an alignment means 16.

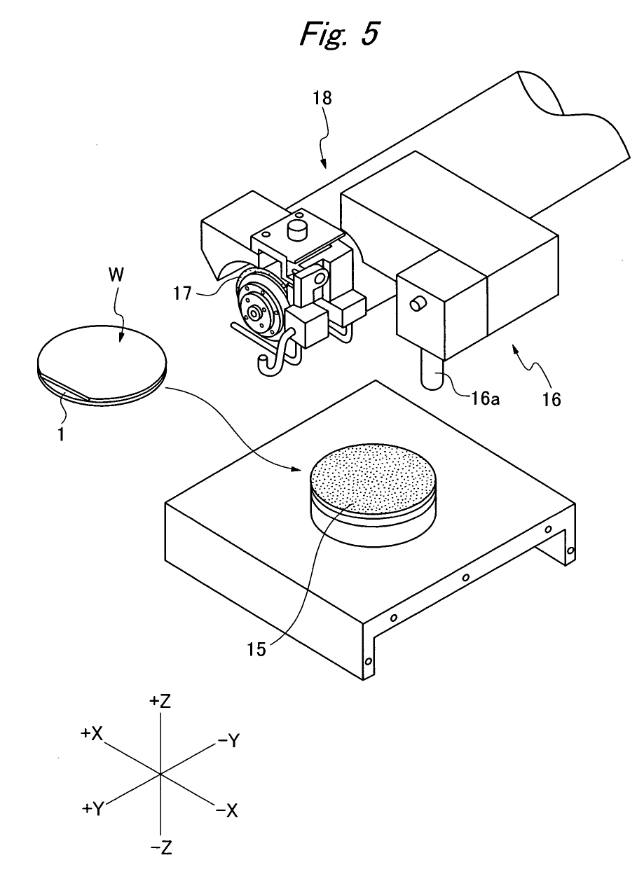

As seen from FIG. 5, the alignment means 16 is combined with a cutting means 18 as a whole, and the cutting means 18 has a cutting blade 17 mounted on the end. The alignment means 16 and cutting means 18 can move together in the y-axial direction.

The alignment means 16 has an infrared ray camera means 16a equipped thereon. While the alignment means 16 and cutting means 18 move together in the y-axial direction, the infrared ray camera means 16a takes pictures of the semiconductor wafer W, which is laid on the chuck table 15 with the rear side up. The pictures of the crossing streets on the semiconductor wafer W are compared with an image of crossing streets preliminarily stored in the alignment means 16 for pattern matching. Thus, a selected street is automatically aligned with the cutting blade 17 in respect of the y-axial direction.

After being aligned with the selected street, the cutting means 18 is lowered, while the chuck table 15 is moved in the +x-axial direction, thereby allowing the descending rotary blade 17 to cut the semiconductor wafer W on the rear side until a predetermined depth is reached.

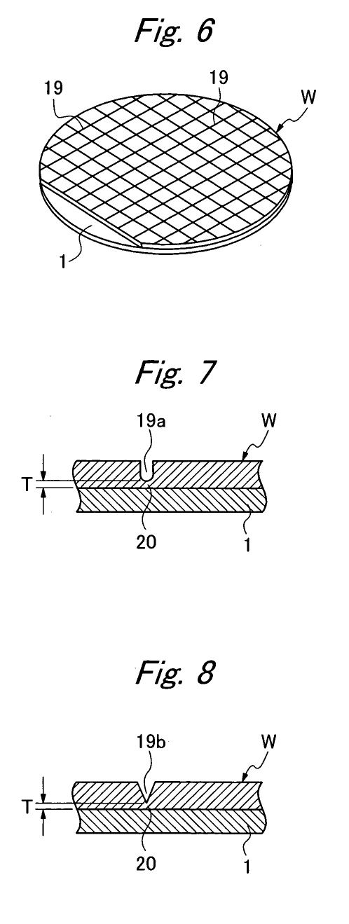

Every time the cutting means 18 is moved the street-to-street distance in the y-axial direction, the street cutting is effected in the x-axial direction. After cutting all streets in the orthogonal direction, the chuck table 15 is rotated 90 degrees to effect the same cuttings in the other orthogonal direction. Thus, the semiconductor wafer W is cut crosswise on the rear side to form the lattice pattern of grooves 19, as shown in FIG. 6 (grooving step).

Each groove 19 thus made has the same shape in cross section as the cutting blade 17. The groove 19 may have a round bottom as a groove 19a in FIG. 7, or may be V-shaped as a groove 19b in FIG. 8. As seen from FIGS. 7 and 8, the grooves 19a and 19b reaches short of the front side, leaving a thin portion 20 remaining uncut on the front side. It is important that a thickness T of the uncut portion 20 should not exceed a thickness which can be removed by the subsequent etching process, and may be, for instance, on the order of 10 μm. To leave the uncut portion 20 in the dicing step effectively prevents appearance of fractures, which otherwise would be caused in the vicinity of the groove if the semiconductor wafer W were cut through in the dicing step. The following description is directed to the example shown in FIG. 8.

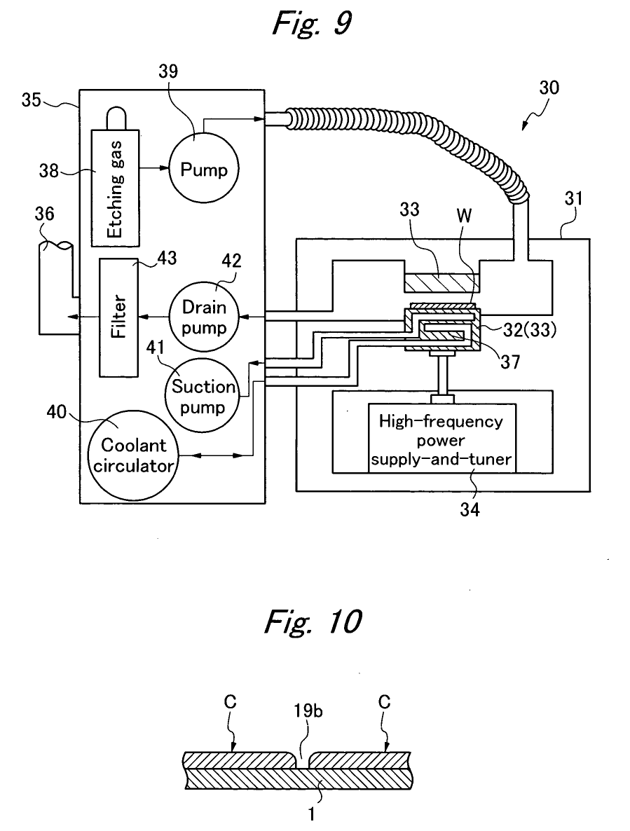

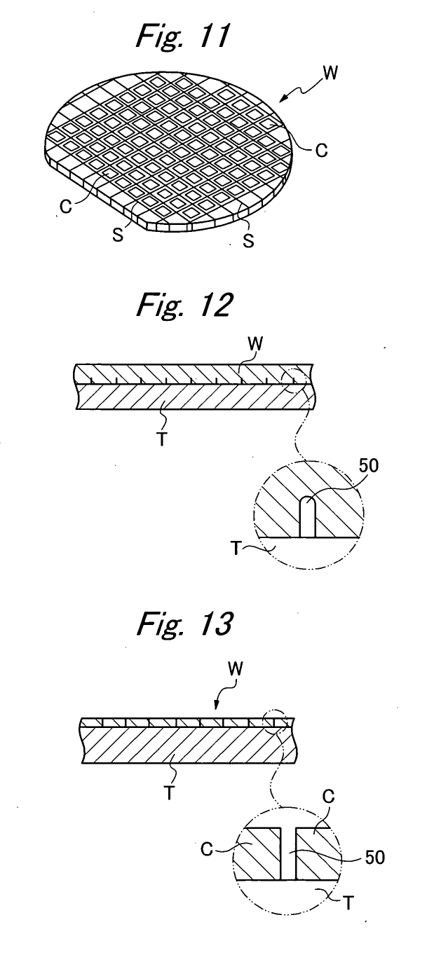

After forming the crosswise pattern of V-shaped grooves 19b on the rear side of the semiconductor wafer W as shown in FIG. 8, a dry etching is effected on the rear side of the semiconductor wafer with use of an etching machine 30 as shown in FIG. 9.

The etching machine 30 generally comprises a chamber 31 for carrying out plasma etching, a gas supply 35 for supplying the plasma etching chamber 31 with an etching gas, and an exhaust pipe 36 for allowing a used gas to escape from the plasma etching chamber 31.

The plasma etching chamber 31 contains a holder 32 for fixedly holding a semiconductor wafer W, a pair of plasma electrodes 33 for producing plasma, a high-frequency power supply-and-tuner 34 for applying a high-frequency voltage across the pair of plasma electrodes 33, and a cooling device 37 for cooling the semiconductor wafer W, where the holder 32 functions as one of the plasma electrodes 33.

The gas supply 35 comprises a reservoir 38 for storing an etching gas such as SF₆+He or CF₄+O₂, a pump 39 for pumping the etching gas from the reservoir 38 to the plasma etching chamber 31, a coolant circulator 40 for supplying the cooling device 37 with cooling water, a suction pump 41 for imparting a sucking force to the holder 32, a drain pump 42 for drawing a used etching gas from the plasma etching chamber 31, and a filter 43 for neutralizing the drawn etching gas to be exhausted through the exhaust pipe 36.

The semiconductor wafer W is fixedly held with the rear side up on the holder 32 in the etching machine 30, and the etching gas is supplied to the plasma etching chamber 31 by the pump 39, and at the same time, the high-frequency power supply-and-tuner 34 applies a high-frequency voltage across the pair of plasma electrodes 33, thereby plasma-etching the semiconductor wafer W on the rear side while the cooling device 37 is supplied with cooling water by the coolant circulator 40.

When the etching treatment is completed, the cutting or grinding distortion layer is removed from the rear side of the semiconductor wafer, while the uncut portion 20 is removed by the etching treatment to make the grooves 19b pass through the front side so as to separate the wafer into the chips C (etching step).

The opposite inner sides of each groove 19b are etched to remove grinding and cutting distortion layers and minute fractures, which were caused at the grooving step. Thus, the anti-breakage strength can be increased substantially and sufficiently.

Some semiconductor wafers W have an etch-resistant layer such as a copper layer formed on its front side, which prevents the etching treatment with an etching gas on the wafer. Preferably, such etch-resistant layer is preliminarily removed mechanically e.g. by grinding before the etching is performed.

The grinding step performed first in the best mode of the present invention is not always necessary. The desired thickness of the semiconductor wafer can be reached only by the etching treatment. In case that the semiconductor wafer is ground on the rear side at the grinding step, the grinding distortion layer caused at the rear side can be removed at the etching step.

### INDUSTRIAL APPLICABILITY

As described above, in a method for dicing a semiconductor wafer according to the present invention, crosswise grooves are made on the rear side of the semiconductor wafer to be in conformity with the crossing streets drawn on the front side at the grooving step, where each groove reaches short of the front side, leaving a portion having a thickness remaining uncut on the front side, and the semiconductor wafer is thereafter etched on the rear side to remove the uncut portions and separate the semiconductor wafer into the chips. The semiconductor chips thus provided are free of cutting distortion layers and fractures. Thus, their anti-breakage strength is substantially increased.

Even if the semiconductor wafer is ground on the rear side prior to the etching step, the semiconductor wafer can be deprived of their grinding distortion layers by etching, and therefore, their anti-breakage strength is substantially increased.

1. A method for dicing a semiconductor wafer into separate chips, each bearing an electrical circuit pattern, said semiconductor wafer having a plurality of chips defined by crossing streets on a front side of the semiconductor wafer, characterized by comprising at least:
a grooving step of making grooves along the crossing streets, each groove extending from a rear side of the semiconductor wafer, reaching short of the front side so as to leave a thickness remaining uncut on the front side; and
an etching step of effecting an etching treatment on the rear side of the semiconductor wafer and on the inner sides of the grooves and the remaining thickness of each groove until the semiconductor wafer is diced into the separate chips.

2. A method for dicing a semiconductor wafer into separate chips according to claim 1, wherein each groove is a V-shaped groove.

3. A method for dicing a semiconductor wafer into separate chips according to claim 1, wherein the etching treatment is effected by means of dry etching.

4. A method for dicing a semiconductor wafer into separate chips according to any one of claims 1 to 3, further comprising a step of grinding the semiconductor wafer on the rear side until a desired thickness of the semiconductor wafer is reached, prior to the grooving step.
